(19) United States
(12) Patent Application Publication
(10) Pub. No.: US 2024/0030820 A1
(43) Pub. Date: Jan. 25, 2024

(54) MODULAR POWER DEVICE PACKAGE EMBEDDED IN CIRCUIT CARRIER

(71) Applicant: Infineon Technologies AG, Neubiberg (DE)

(72) Inventors: Angela Kessler, Sinzing (DE); Eung San Cho, Torrance, CA (US); Danny Clavette, Greene, RI (US)

(21) Appl. No.: 17/870,405

(22) Filed: Jul. 21, 2022

(51) Int. Cl. H02M 3/158; H02M 3/157; H02M 3/335

(52) U.S. Cl. CPC H02M 3/1584; H02M 3/157; H02M 3/33571

(57) ABSTRACT

A power semiconductor module arrangement includes a circuit carrier including an electrically insulating substrate and an upper metallization layer disposed on upper side of the electrically insulating substrate, and a plurality of power stage inlays that each include first and second transistor dies and a driver die configured to control switching of the first and second transistor dies. Each of the power stage inlays are modular units comprising terminals that are electrically connected to the first and second transistor dies and the driver die. Each of the power stage inlays is embedded within the electrically insulating substrate. The upper metallization layer comprises conductive connectors that extend over the power stage inlays and connect with the terminals of the terminals of each of the power stage inlays.

### BACKGROUND

Many applications such as automotive and industrial applications use half-bridge and full-bridge circuits as power conversion devices. Half-bridge and full-bridge circuits include power switching devices that perform power conversion by rapidly switching on and off. It is desirable to improve performance parameters in power conversion circuits, e.g., power loss, current density, power consumption, with a small areal footprint and robust electrical interconnections. Conventional semiconductor packaging solutions have reached physical limits with respect to these performance parameters. There is a need to provide high performance power conversion device solutions.

### SUMMARY

A power semiconductor module arrangement is disclosed. According to an embodiment, the power semiconductor module arrangement comprises a circuit carrier comprising an electrically insulating substrate and an upper metallization layer disposed on upper side of the electrically insulating substrate, and a plurality of power stage inlays that each comprise first and second transistor dies and a driver die configured to control switching of the first and second transistor dies, wherein each of the power stage inlays are modular units comprising terminals that are electrically connected to the first and second transistor dies and the driver die, wherein each of the power stage inlays is embedded within the electrically insulating substrate, and wherein the upper metallization layer comprises conductive connectors that extend over the power stage inlays and connect with the terminals of the terminals of each of the power stage inlays.

A method of producing a power semiconductor module arrangement is disclosed. According to an embodiment, the method comprises providing a plurality of power stage inlays that each comprise first and second transistor dies and a driver die configured to control switching of the first and second transistor dies, embedding each of the power stage inlays within an electrically insulating substrate, and forming an upper metallization layer on an upper side of the electrically insulating substrate, wherein each of the power stage inlays are modular units comprising terminals that are electrically connected to the first and second transistor dies and the driver die, and wherein the upper metallization layer comprises conductive connectors that extend over the power stage inlays and connect with the terminals of each of the power stage inlays.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a power stage inlay, according to an embodiment.

FIG. 2 illustrates a power semiconductor module arrangement with a plurality of power stage inlays embedded within a circuit carrier, according to an embodiment.

FIG. 3, which includes FIGS. 3A and 3B, illustrates selected method steps for forming a circuit carrier with power stage inlays embedded therein, according to an embodiment.

FIG. 4, which includes FIGS. 4A and 4B, illustrates selected method steps for forming a circuit carrier with power stage inlays embedded therein, according to an embodiment.

FIG. 5, which includes FIGS. 5A, 5B, and 5C, illustrates selected method steps for forming a circuit carrier with power stage inlays embedded therein, according to an embodiment.

FIG. 6, which includes FIGS. 6A, 6B, and 6C, illustrates selected method steps for embedding a power stage inlay within a circuit carrier, according to an embodiment.

FIG. 7, which includes FIGS. 7A, 7B, and 7C, illustrates selected method steps for embedding a power stage inlay within a circuit carrier, according to an embodiment.

### DETAILED DESCRIPTION

Embodiments of a power semiconductor module arrangement comprising a plurality of power stage inlays embedded within a circuit carrier are described herein. The power stage inlays are modular devices that can be assembled in a large grouping comprising, e.g., four, eight, sixteen, thirty-two, etc., of the power stage inlays together. Each power stage inlay can be an integrated power conversion circuit such as an integrated half-bridge or full-bridge circuit. The power stage inlay can be embedded within the circuit carrier through a variety of different techniques, which may include forming a dielectric resin around the power stage inlay and forming a metallization over the dielectric resin. The power stage inlays are arranged to allow for vertical current flow and for electrical accessibility of the I/O terminals at an upper side of the device. This arrangement allows for optimal space efficiency and vertical current flow in a multi-layered assembly.

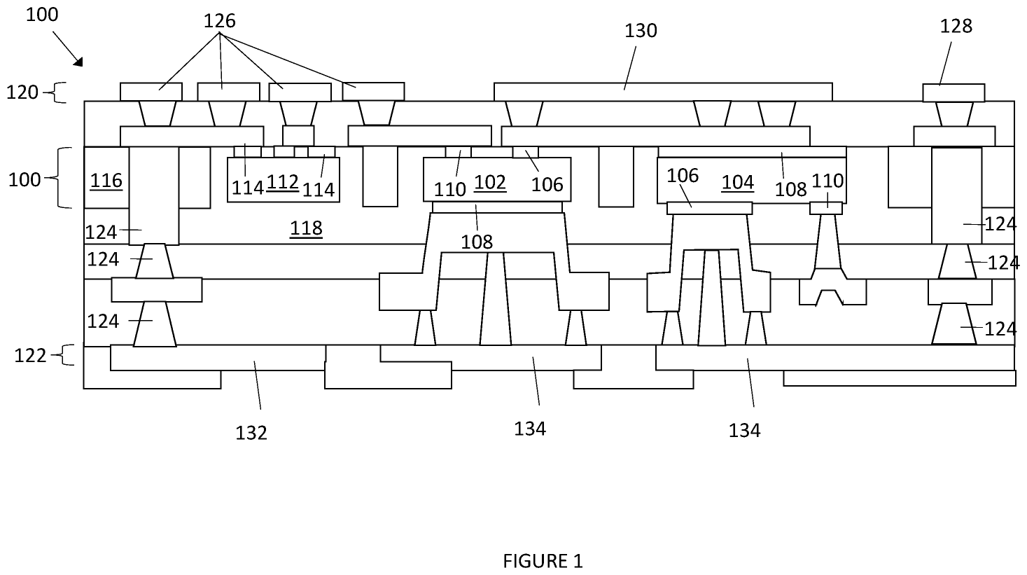

Referring to FIG. 1, a power stage inlay 100 comprises first and second transistor dies 102, 104. The first and second transistor dies 102, 104 may be configured as discrete switching devices, e.g., MOSFETs (Metal Oxide Semiconductor Field Effect Transistors), IGBTs (Insulated Gate Bipolar Transistors), and HEMTs (High Electron Mobility Transistors), for example. According to an embodiment, the first and second transistor dies 102, 104 are each configured as discrete power transistors that are rated to accommodate voltages of at least 100 V (volts), at least 600 V, at least 600 1200V or more and/or rated to accommodate currents of at least 1 A (amperes), at least 10 A, at least 50 A, at least 100 A or more. The first and second transistor dies 102, 104 may be formed in any device technology and may include IV semiconductor materials, e.g., silicon, silicon germanium, silicon carbide, etc., and/or type III-V semiconductor materials, e.g., gallium nitride, gallium arsenide, etc. According to an embodiment, the first and second transistor dies 102, 104 are configured as vertical devices that conduct current in a vertical direction between a main surface and a rear surface of the respective semiconductor die. To this end, the first and second transistor dies 102, 104 each comprise a first load terminal 106 disposed on a main surface and a second load terminal 108 disposed on a rear surface of the respective semiconductor die. The first and second load terminals 106, 108 are the voltage blocking terminals of the device, e.g., source and drain terminals in the case of a MOSFET, collector and emitter terminals in the case of an IGBT, etc. The first and second transistor dies 102, 104 additionally each comprise a gate terminal 110 disposed on the main surface of the respective semiconductor die. As shown, the orientation of the first and second transistor dies 102, 104 is reversed such that the main and rear surfaces of these dies face in opposite directions from one another.

The power stage inlay 100 additionally comprises a driver die 112 that is configured to control the switching operations of the first and second transistor dies 102, 104. The driver die 112 may be a logic device, such as a silicon based integrated circuit, for example. The driver die 112 comprises a plurality of I/O (input/output) terminals 114 disposed on a main surface the driver die 112 that faces a main or upper surface of the power stage inlay 100.

According to an embodiment, the power stage inlay 100 is configured as an integrated half-bridge circuit. A half-bridge circuit refers to one type of circuit topology that is used in a power conversion circuit, such as a DC to DC converter, DC to AC converter, etc. A half-bridge circuit comprises a high-side switch connected in series with a low-side switch. One load terminal of the high-side switch (e.g., the drain) is connected to a first DC voltage (e.g., a positive potential), one load terminal of the low-side switch (e.g., the source) is connected to a second DC voltage (e.g., negative potential or ground), and the remaining two load terminals (e.g., the source of the high-side switch and the drain of the low-side switch) are connected together to form the output of the half-bridge circuit. The control terminals of the high-side switch and the low-side switch (e.g., the gate terminals) can be switched according to a power control scheme (e.g., pulse width modulation) to produce a desired voltage and frequency at the output of the half-bridge circuit. In an embodiment wherein the power stage inlay 100 is configured as an integrated half-bridge circuit, the first transistor die 102 is be the high-side switch of the half-bridge circuit, the second transistor die 104 is the low-side switch of the half-bridge circuit, and the driver die 112 is configured control the switching of the first and second transistor dies 102, 104 using a power control scheme.

According to an embodiment, the power stage inlay 100 is a laminate device. A laminate device refers to a type of semiconductor packaging wherein a plurality of constituent layers of dielectric material are laminated on top of one another. The first and second transistor dies 102, 104 and the driver die 112 are embedded within a laminated dielectric substrate portion of the power stage inlay 100. The power stage inlay 100 may comprise a core laminate layer 116, which may be formed from e.g., pre-preg material such as FR-4, FR-5, CEM-4. The first and second transistor dies 102, 104 and the driver die 112 may be arranged within openings in the core laminate layer 116 and encapsulated by a resin 118 such as bismaleimide trazine (BT) resin. Additional constituent laminate layers may be provided from e.g., pre-preg material and/or or resin material. The power stage inlay 100 comprises a plurality of structured metallization layers formed on each one of the constituent laminate layers. Included in these metallization layers are a first metallization layer 120 which forms an outermost layer at a main or upper side of the laminate substrate, and a second metallization layer 122 which forms an outermost layer at a rear or lower side of the laminate substrate. Each of these metallization layers comprise electrically conductive metals such as copper (Cu), aluminium (Al), nickel (Ni), silver (Ag), palladium (Pd) gold (Au), etc., and alloys or combinations thereof. Vertical connection between the various metallization layers may be provided by vias 124. The vias 124 may comprise electrically conductive metals such as copper, aluminium, tungsten, nickel, etc., and alloys or combinations thereof. A surface plating such as an ENEPIG (electroless nickel electroless palladium immersion gold) layer, for example, may be provided on outer surfaces of first and/or second metallization layers 120, 122, so as to enhance adhesion and/or provide anticorrosion. The power stage inlay 100 may further comprise a solder resist, such as a polymer material, disposed between structured regions of the first and/or second metallization layers 120, 122.

The terminals of the power stage inlay 100 comprise a group of upper surface terminals formed in the first metallization layer 120. In particular, the power stage inlay 100 comprises a plurality of upper I/O terminals 126 that are electrically connected to I/O terminals 114 of the driver die 112. The upper surface terminals additionally comprise upper voltage supply terminals 128 disposed on the upper side of the power stage inlay 100. The upper voltage supply terminals 128 are electrically connected to load terminals from the first and second transistor dies 102, 104. The power stage inlay 100 comprises through-via connections that electrically connect the upper voltage supply terminals 128 to the load terminals from the first and second transistor dies 102, 104 that face away from the upper side of the respective power stage inlay 100. In particular, the upper voltage supply terminals 128 may comprise a reference potential terminal (e.g., GND or negative potential) that is electrically connected to the first load terminal 106 of the second transistor die 104 (as shown in the cross-sectional view of FIG. 1) and an input voltage terminal (e.g., positive potential relative to ground) that is electrically connected to the first load terminal 106 of the first transistor die 102 (in another cross-sectional view from that shown in FIG. 1). Additionally, the power stage inlay 100 comprises an upper switch node terminal 130=. The upper switch node terminal 130 may correspond to an output terminal of the half-bridge circuit.

The terminals of the power stage inlay 100 may additionally comprise a group of lower surface terminals formed in the second metallization layer 122. According to an embodiment, lower surface terminals comprise a plurality of lower I/O terminals 132 formed in the second metallization layer 122. The lower I/O terminals 132 may provide corresponding connectivity to each of the upper I/O terminals 126, wherein the vias 124 provide a vertical connection through the power stage inlay 100. The lower surface terminals may additionally comprise lower voltage supply terminals 134 that are connected the upper voltage supply terminals 128.

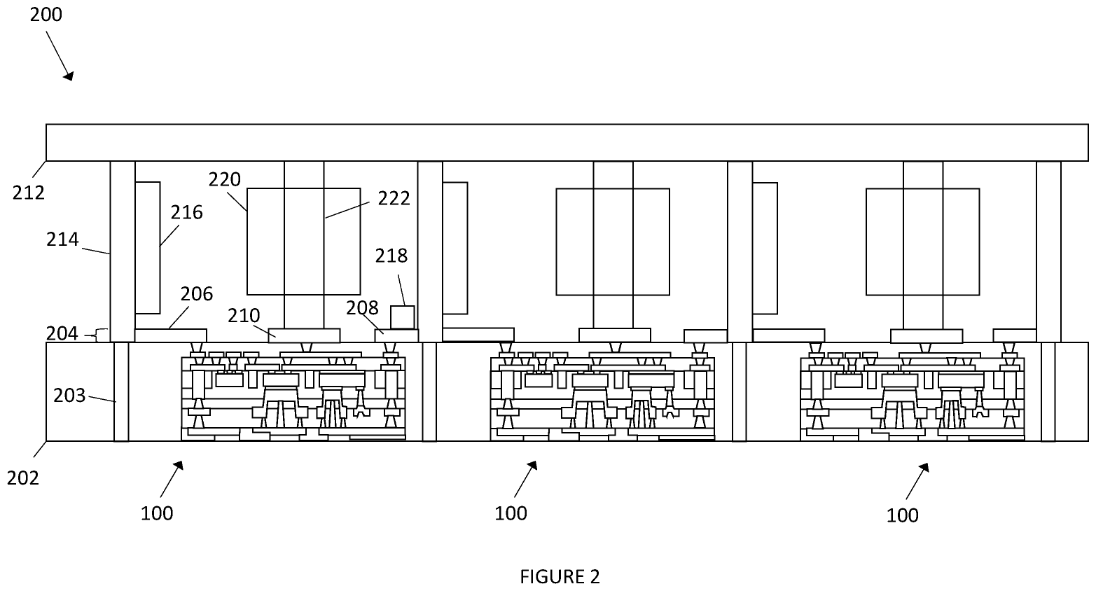

Referring to FIG. 2, a power semiconductor module arrangement 200 that comprises a circuit carrier 202 and power stage inlays 100 embedded within the circuit carrier 202 is shown. The circuit carrier 202 comprises an electrically insulating substrate and an upper metallization layer 204 disposed on upper side of the electrically insulating substrate. The circuit carrier 202 can be constructed in a similar way as a PCB (printed circuit board). The electrically insulating substrate can comprise laminate materials such as such as FR-4, FR-5, CEM-4, etc., or resin material such as bismaleimide trazine (BT) resin. The upper metallization layer 204 can be formed from metals such as copper (Cu), aluminium (Al), nickel (Ni), silver (Ag), palladium (Pd) gold (Au), etc., and alloys or combinations thereof.

Each of the power stage inlays 100 is embedded within the electrically insulating substrate of the circuit carrier 202. Exemplary techniques for embedding the power stage inlays 100 and corresponding arrangements of the circuit carrier 202 will be described in further detail below. The upper metallization layer 204 is structured into conductive connectors that extend over the power stage inlays 100 and connect with the upper surface terminals of the power stage inlays 100. These conductive connectors comprise I/O connectors 206 that extend over and are electrically connected with the upper I/O terminals 126, upper voltage supply connectors 208 that extend over and are electrically connected with the upper voltage supply terminals 128, and upper switch node connectors 210 that extend over and are electrically connected with the upper switch node terminals 130. The circuit carrier 202 comprises through-vias 203 that extend through the circuit carrier 202. These through-vias 203 may be used for power connections and/or a vertical return path.

The power semiconductor module arrangement 200 comprises a second circuit carrier 212 vertically spaced apart from the circuit carrier 202, and a third circuit carrier 214 vertically extending between the first circuit carrier 202 and the second circuit carrier 212. The second and third circuit carriers 212, 214 may be a printed circuit board or other type of circuit carrier e.g., DCB, IMB, AMB, etc. The third circuit carrier 214 is arranged to provide power connections to the first circuit carrier 202, e.g., input voltage, and a ground connection return path. Additionally, third circuit carrier 214 may accommodate a controller 216 that is electrically connected to the I/O terminals of the driver die 112 for each power stage inlay 100 via the I/O connectors 206.

The power semiconductor module arrangement 200 comprises a plurality of passive elements 218 mounted on the upper side of the circuit carrier 202. At least some of the passive elements are electrically connected to the terminals of each of the power stage inlays 100 by the conductive connectors. The passive elements 218 can comprise any type of discrete device, e.g., resistor, capacitor, inductor. At least some of the passive elements may be discrete capacitors that are part of the power conversion circuits formed by the power stage inlays 100, e.g., resonant capacitors, output capacitors, etc.

According to an embodiment, the passive elements comprise a discrete inductor 220 mounted over each one of the power stage inlays 100. Each discrete inductor 220 comprises an outer body comprising an electrically insulating material such as epoxy, resin, ceramic, etc., and a conductive core 222 arranged within the outer body. The conductive core 222 forms the inductive winding of the discrete inductor that provides a defined inductance. A portion of the conductive core may be exposed at an upper side of the outer body and form a heat sink. The discrete inductor 220 further comprises leads (as shown) or contacts at a lower side of the outer body. The discrete inductor 220 may be configured as an output inductor that is electrically connected to the output of the power stage inlays 100 via the upper switch node terminals 130.

The power stage inlays 100 embedded within the circuit carrier 202 facilitate vertical current flow in the power semiconductor module arrangement 200. Due to the arrangement of the upper I/O terminals 126, short and direct connections can be made between the controller 216 and the driver die 112. The modular configuration of the power stage inlays 100 enables the assembly of a large array of power conversion circuits within a small areal footprint, as each power stage inlay 100 can be placed close to one another and embedded within the within the circuit carrier 202 according to the techniques described below.

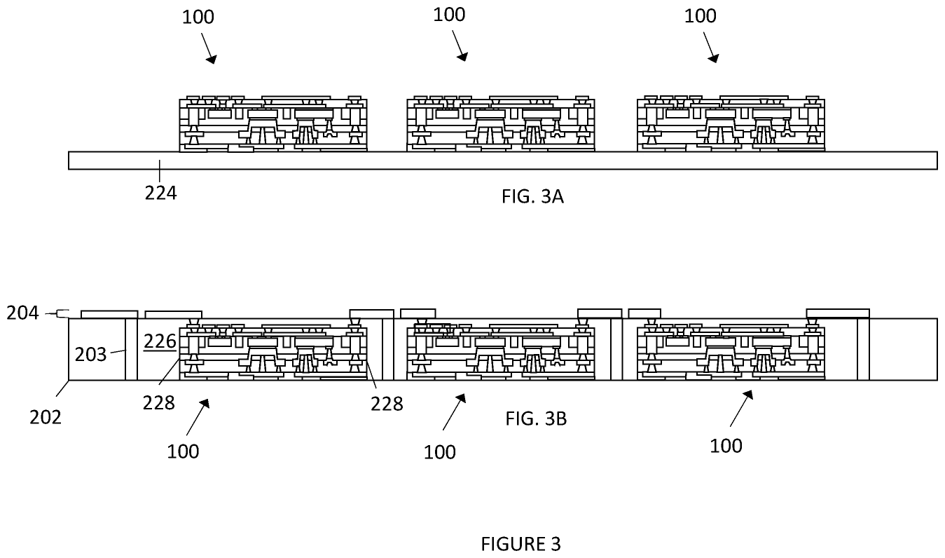

Referring to FIG. 3, a technique for forming the circuit carrier 202 with each of the power stage inlays 100 being embedded within an electrically insulating substrate region of the circuit carrier 202 is shown, according to an embodiment. As shown in FIG. 3A, a temporary carrier 224 is provided. The temporary carrier 224 may be a releasable tape, such as a polycarbonate tape, for example. A plurality of the power stage inlays 100 is arranged on the temporary carrier 224. Subsequently, as shown in FIG. 3B, a dielectric resin 226 is formed to encapsulate each one of the power stage inlays 100. The dielectric resin 226 may be a curable dielectric resin 226 such as bismaleimide trazine (BT) resin, for example. The dielectric resin 226 is formed to contact the outer edge sides 228 of each the power stage inlays 100. As shown, the dielectric resin 226 may be formed to cover the upper surfaces of the power stage inlays 100 as well. After the dielectric resin 226 is hardened, the upper metallization layer 204 of the circuit carrier 202 can be formed with the connectors that extend over the power stage inlays 100 and connect with the terminals of each of the power stage inlays 100. The upper metallization layer 204 can be formed by metal a deposition technique, e.g., a plating technique, for example. Alternatively, the upper metallization layer 204 can be a pre-patterned layer that is bonded to the dielectric resin 226. Vias may be formed between the upper terminals of the power stage inlays 100 and the upper metallization layer 204 to complete the electrical connections. In addition, the through-vias 203 that extend through the circuit carrier 202 may be formed by etching or drilling complete holes in the dielectric resin 226.

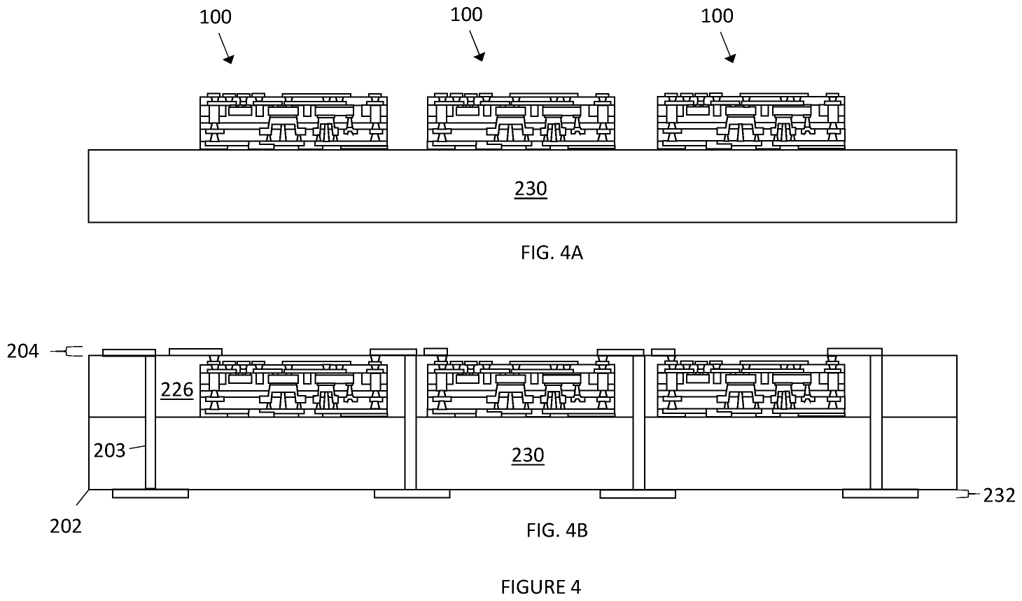

Referring to FIG. 4, a technique for forming the circuit carrier 202 with each of the power stage inlays 100 being embedded within an electrically insulating substrate region of the circuit carrier 202 is shown, according to an embodiment. As shown in FIG. 4A, a printed circuit board 230 is provided. The printed circuit board 230 can be a pre-fabricated and/or commercially available device comprising a dielectric substrate of, e.g., prepreg materials, and metallization layers. A plurality of the power stage inlays 100 is arranged on printed circuit board 230. The printed circuit board 230 may comprise an upper surface metallization (not shown) that accommodates the mounting of the power stage inlays 100 and electrical connection thereto. As shown in FIG. 4B, the dielectric resin 226 is formed on the printed circuit board 230 to encapsulate each one of the power stage inlays 100 in a similar manner as described above. Different to the previous embodiment, in this case the carrier that accommodates the mounting of the power stage inlays 100 (printed circuit board 230) remains as part of the completed circuit carrier 202. The through-vias 203 may be formed by drilling complete holes through the dielectric resin 226 and the printed circuit board 230. Alternatively, the printed circuit board 230 may be initially provided with through-via structures and the dielectric resin 226 may be processed to complete electrical connections thereto. As shown, the circuit carrier 202 may comprise a rear side metallization 232 comprising rear side terminals that can be electrically accessed by the through-vias 203.

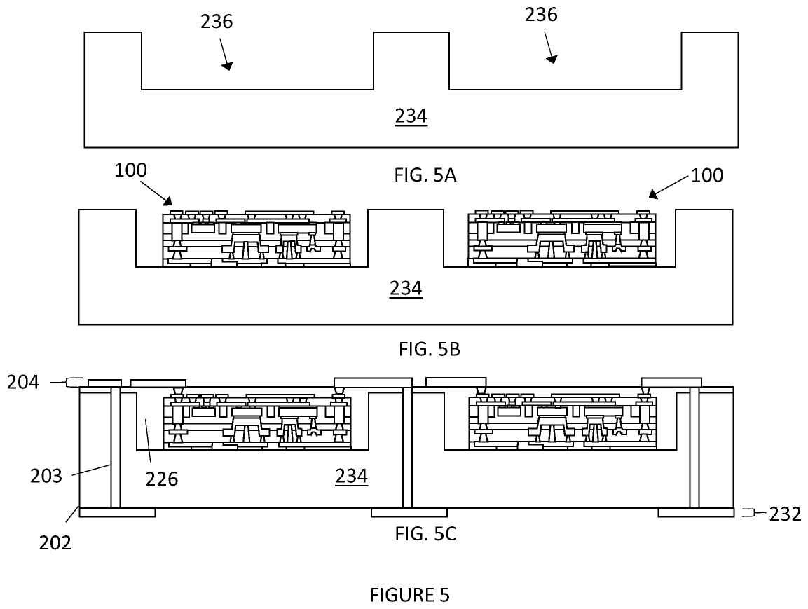

Referring to FIG. 5, a technique for forming the circuit carrier 202 with each of the power stage inlays 100 being embedded within an electrically insulating substrate region of the circuit carrier 202 is shown, according to an embodiment. As shown in FIG. 5A, a dielectric core structure 234 is provided. The dielectric core structure 234 can be a pre-formed rigid structure comprising dielectric materials such as fiber materials and/or woven glass fiber materials, e.g., FR-4, FR-5, CEM-4, etc. The dielectric core structure 234 is provided with a plurality of recesses 236. The recesses 236 extend from an upper surface of the dielectric core structure 234 and comprise lower surfaces that extend between opposing sidewalls. As shown in FIG. 5B, the power stage inlays 100 are arranged within the recesses 236. In this case, one of the power stage inlays 100 is arranged within each one of the recesses 236. As shown in FIG. 5C, the dielectric resin 226 is formed around the power stage inlays 100 within the recesses 236. Subsequently, the upper metallization layer 204 and the through-vias 203 may be formed.

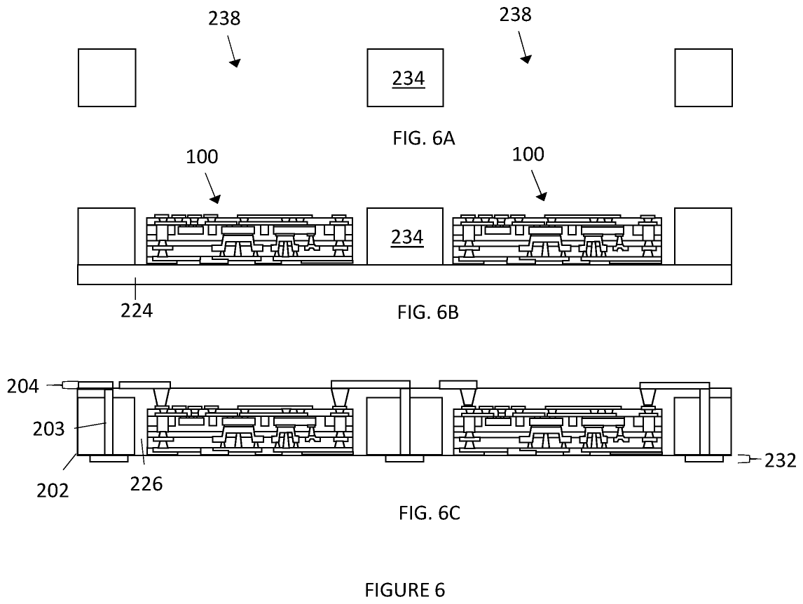

Referring to FIG. 6, a technique for forming the circuit carrier 202 with each of the power stage inlays 100 being embedded within an electrically insulating substrate region of the circuit carrier 202 is shown, according to an embodiment. The embodiment of FIG. 6 is substantially similar to that of FIG. 5, except that the dielectric core structure 234 comprises openings 238 that extend completely through the dielectric core structure 234. As shown in FIG. 6B, the dielectric core structure 234 comprising the openings 238 is provided on a temporary carrier 224, and each of the power stage inlays 100 are placed on the temporary carrier 224 before forming the dielectric resin 226. As shown in FIG. 6B, the dielectric resin 226 is formed around the power stage inlays 100 within the openings 238. Subsequently, the upper metallization layer 204 and the through-vias 203 may be formed.

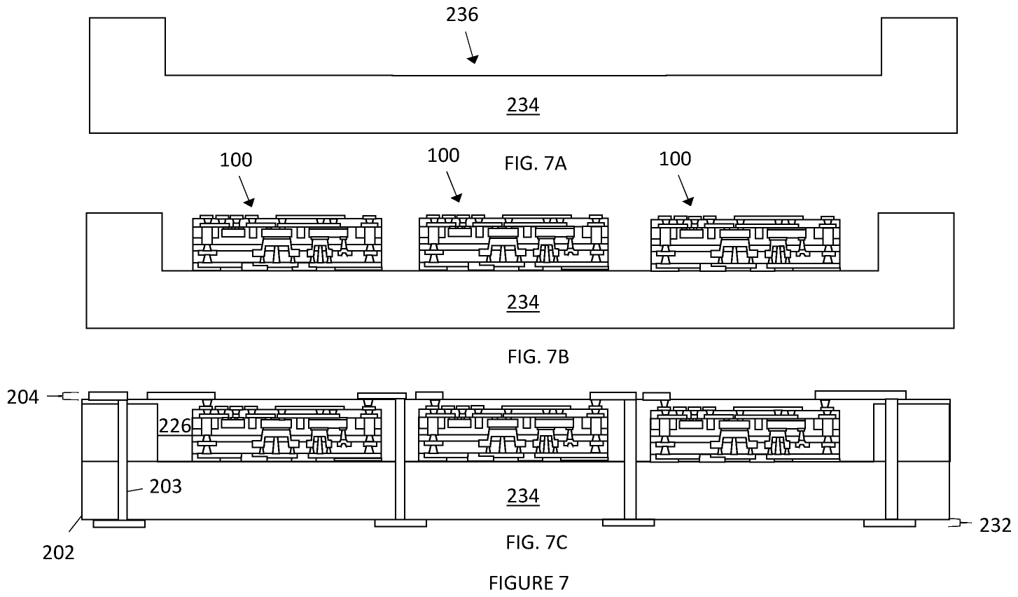

Referring to FIG. 7, a technique for forming the circuit carrier 202 with each of the power stage inlays 100 being embedded within an electrically insulating substrate region of the circuit carrier 202 is shown, according to an embodiment. In the embodiment of FIG. 7, a plurality of the power stage inlays 100 is arranged within one of the recesses 236. As shown in FIG. 7B, three of the power stage inlays 100 is arranged with one recess. In principle, any number of the power stage inlays 100, e.g., three, four, five, etc., can be arranged within one recess 236. Moreover, this pattern can be repeated multiple times. After arranging multiple power stage inlays 100 within one of the recesses 236, the dielectric resin 226 is formed so as to encapsulate each of the power stage inlays 100 and form a lateral isolation structure in between each of the power stage inlays 100. This technique may be preferable as a way to increase the space-efficiency of the power stage inlays 100 in comparison to the previously disclosed techniques. A similar technique may be used for a dielectric core structure 234 comprising complete openings 238, e.g., as described with reference to FIG. 6.

In any of the embodiments described herein, the power stage inlay 100 may be configured as a molded package instead of a laminate device. In that case, the power stage inlay 100 may comprise an electrically conductive lead frame, e.g., a lead frame comprising copper, aluminum, etc. comprising a die pad or pads and a plurality of leads extending away from the die pad or pads. The first and second transistor dies 102, 104 and the driver die 112 may be mounted on the die pad or pads and electrically connected to the leads using interconnect elements such as bond wires, clips, ribbons, etc. An electrically insulating encapsulant material such as a mold compound or thermosetting plastic may be used to encapsulate and protect the dies.

Although the present disclosure is not so limited, the following numbered examples demonstrate one or more aspects of the disclosure.

Example 1. A power semiconductor module arrangement comprises a circuit carrier comprising an electrically insulating substrate and an upper metallization layer disposed on upper side of the electrically insulating substrate, and a plurality of power stage inlays that each comprise first and second transistor dies and a driver die configured to control switching of the first and second transistor dies, wherein each of the power stage inlays are modular units comprising terminals that are electrically connected to the first and second transistor dies and the driver die, wherein each of the power stage inlays is embedded within the electrically insulating substrate, and wherein the upper metallization layer comprises conductive connectors that extend over the power stage inlays and connect with the terminals of the terminals of each of the power stage inlays.

Example 2. The power semiconductor module arrangement of example 1, wherein the electrically insulating substrate comprises a dielectric resin that contacts outer edge sides of the power stage inlays.

Example 3. The power semiconductor module arrangement of example 2, wherein the electrically insulating substrate region further comprises a dielectric core structure, and wherein each of the power stage inlays is arranged on or within the dielectric core structure.

Example 4. The power semiconductor module arrangement of example 3, wherein the dielectric core structure comprises one or more recesses, and wherein each of the power stage inlays is arranged within the one or more recesses.

Example 5. The power semiconductor module arrangement of example 3, wherein two or more of the of the power stage inlays are arranged within one of the recesses.

Example 6. The power semiconductor module arrangement of example 1, wherein each of the power stage inlays comprise a plurality of upper I/O terminals disposed on an upper side of the respective power stage inlay, and wherein the conductive connectors comprise I/O connectors that extend over and are in direct ohmic contact with the upper I/O terminals.

Example 7. The power semiconductor module arrangement of example 6, wherein each of the power stage inlays of lower I/O terminals disposed on a lower side of the respective power stage inlay, and wherein each of the power stage inlays comprise through-via connections electrically connecting the upper I/O terminals and the lower I/O terminals of the respective power stage inlay.

Example 8. The power semiconductor module arrangement of example 1, wherein each of the power stage inlays comprise a plurality of upper voltage supply terminals disposed on an upper side of the respective power stage inlay, wherein the upper voltage supply terminals are electrically connected to load terminals from the first and second transistor dies, and wherein the conductive connectors comprise voltage supply connectors that extend over and are in direct ohmic contact with the upper voltage supply terminals.

Example 9. The power semiconductor module arrangement of example 8, wherein each of the power stage inlays comprise through-via connections that electrically connect the upper voltage supply terminals are electrically connected to the load terminals from the first and second transistor dies that face away from the upper side of the respective power stage inlay.

Example 10. The power semiconductor module arrangement of example 1, wherein the power stage inlays are each configured as integrated half-bridge circuits, and wherein the first and second transistor dies of the power stage inlays form the high-side switch and the low-side switch of the integrated half-bridge circuit, respectively.

Example 11. The power semiconductor module arrangement of example 10, wherein the first and second transistor dies of each of the power stage inlays are configured as vertical devices with first and second load terminals disposed on opposite sides of the respective transistor die.

Example 12. The power semiconductor module arrangement of example 1, further comprising a plurality of passive elements mounted on the upper side of the circuit carrier, and wherein at least some of the passive elements are electrically connected to the terminals of each of the power stage inlays by the conductive connectors.

Example 13. The power semiconductor module arrangement of example 12, wherein the passive elements comprise a discrete inductor mounted over each one of the power stage inlays, wherein each of the discrete inductors is mounted such that a lower lead or contact of the respective discrete inductor is electrically connected to one of the terminals of the power stage inlays by one of the conductive connectors, and wherein each of the discrete inductors comprises a conductive core that is exposed from an upper side of the respective discrete inductor that is opposite from the upper side of the circuit carrier.

Example 14. The power semiconductor module arrangement of example 1, wherein each of the power stage inlays are laminate devices composing a plurality of laminate dielectric layers and structured metallization layers stacked on the laminate dielectric layers, and wherein the terminals are provided from outermost ones of the structured metallization layers.

Example 15. A method of producing a power semiconductor module arrangement comprises providing a plurality of power stage inlays that each comprise first and second transistor dies and a driver die configured to control switching of the first and second transistor dies, and embedding each of the power stage inlays within an electrically insulating substrate, forming an upper metallization layer on an upper side of the electrically insulating substrate, wherein each of the power stage inlays are modular units comprising terminals that are electrically connected to the first and second transistor dies and the driver die, and wherein the upper metallization layer comprises conductive connectors that extend over the power stage inlays and connect with the terminals of each of the power stage inlays.

Example 16. The method of example 15, wherein embedding the plurality of power stage inlays comprises forming a dielectric resin that contacts outer edge sides of the power stage inlays.

Example 17. The method of example 16, wherein embedding the plurality of power stage inlays further comprises providing a dielectric core structure and arranging the power stage inlays on or within the dielectric core structure.

Example 18. The method of example 17, wherein the dielectric core structure is provided to comprise one or more recesses extending from an upper surface of the dielectric core structure, and wherein embedding the plurality of power stage inlays further comprises arranging one or more of the power stage inlays within the one or more recesses, and forming the dielectric resin around the power stage inlays within the one or more recesses.

Example 19. The method of example 18, wherein embedding the plurality of power stage inlays comprises arranging a plurality of the power stage inlays within one of the recesses, and forming the dielectric resin around each of the power stage inlays within the one of the recesses.

Example 20. The method of example 17, wherein the dielectric core structure is provided to comprise one or more openings that extend completely from the upper surface of the dielectric core structure to a rear surface of the dielectric core structure, wherein the method further comprises providing a temporary carrier, and arranging each one of the power stage inlays on the temporary carrier before forming the dielectric resin.

Example 21. The method of example 16, wherein embedding the plurality of power stage inlays further comprises providing a temporary carrier, and arranging each one of the power stage inlays on the temporary carrier before forming the dielectric resin.

Example 22. The method of example 16, further comprising providing a printed circuit board, and wherein embedding the plurality of power stage inlays further comprises arranging each one of the power stage inlays on the printed circuit board, and forming the dielectric resin over each one of the power stage inlays and on the printed circuit board.

Example 23. The method of example 15, wherein each of the power stage inlays comprise a plurality of upper I/O terminals disposed on an upper side of the respective power stage inlay, and wherein the conductive connectors are formed to comprise I/O connectors that extend over and are in direct ohmic contact with the upper I/O terminals.

Example 24. The method of claim 15, wherein the power stage inlays are each configured as integrated half-bridge circuits, and wherein the first and second transistor dies of the power stage inlays form the high-side switch and the low-side switch of the integrated half-bridge circuit, respectively.

Example 25. The method of example 15, wherein the first and second transistor dies of each of the power stage inlays are configured as vertical devices with first and second load terminals disposed on opposite sides of the respective transistor die.

Example 26. The method of example 15, further comprising mounting a plurality of passive elements mounted on the upper side of the electrically insulating substrate, wherein at least some of the passive elements are electrically connected to the terminals of each of the power stage inlays by the conductive connectors.

Example 27. The method of example 26, wherein mounting the plurality of passive elements comprises mounting a discrete inductor mounted over each one of the power stage inlays, wherein each of the discrete inductors is mounted such that a lower lead or contact of the respective discrete inductor is electrically connected to one of the terminals of the power stage inlays by one of the conductive connectors, and wherein each of the discrete inductors comprises a conductive core that is exposed from an upper side of the respective discrete inductor that is opposite from the upper side of the circuit board.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A power semiconductor module arrangement, comprising:
a circuit carrier comprising an electrically insulating substrate and an upper metallization layer disposed on upper side of the electrically insulating substrate; and
a plurality of power stage inlays that each comprise first and second transistor dies and a driver die configured to control switching of the first and second transistor dies,
wherein each of the power stage inlays are modular units comprising terminals that are electrically connected to the first and second transistor dies and the driver die,
wherein each of the power stage inlays is embedded within the electrically insulating substrate, and
wherein the upper metallization layer comprises conductive connectors that extend over the power stage inlays and connect with the terminals of the terminals of each of the power stage inlays.

2. The power semiconductor module arrangement of claim 1, wherein the electrically insulating substrate comprises a dielectric resin that contacts outer edge sides of the power stage inlays.

3. The power semiconductor module arrangement of claim 2, wherein the electrically insulating substrate region further comprises a dielectric core structure, and wherein each of the power stage inlays is arranged on or within the dielectric core structure.

4. The power semiconductor module arrangement of claim 3, wherein the dielectric core structure comprises one or more recesses, and wherein each of the power stage inlays is arranged within the one or more recesses.

5. The power semiconductor module arrangement of claim 3, wherein two or more of the of the power stage inlays are arranged within one of the recesses.

6. The power semiconductor module arrangement of claim 1, wherein each of the power stage inlays comprise a plurality of upper I/O terminals disposed on an upper side of the respective power stage inlay, and wherein the conductive connectors comprise I/O connectors that extend over and are in direct ohmic contact with the upper I/O terminals.

7. The power semiconductor module arrangement of claim 6, wherein each of the power stage inlays of lower I/O terminals disposed on a lower side of the respective power stage inlay, and wherein each of the power stage inlays comprise through-via connections electrically connecting the upper I/O terminals and the lower I/O terminals of the respective power stage inlay.

8. The power semiconductor module arrangement of claim 1, wherein each of the power stage inlays comprise a plurality of upper voltage supply terminals disposed on an upper side of the respective power stage inlay, wherein the upper voltage supply terminals are electrically connected to load terminals from the first and second transistor dies, and wherein the conductive connectors comprise voltage supply connectors that extend over and are in direct ohmic contact with the upper voltage supply terminals.

9. The power semiconductor module arrangement of claim 8, wherein each of the power stage inlays comprise through-via connections that electrically connect the upper voltage supply terminals are electrically connected to the load terminals from the first and second transistor dies that face away from the upper side of the respective power stage inlay.

10. The power semiconductor module arrangement of claim 1, wherein the power stage inlays are each configured as integrated half-bridge circuits, and wherein the first and second transistor dies of the power stage inlays form the high-side switch and the low-side switch of the integrated half-bridge circuit, respectively.

11. The power semiconductor module arrangement of claim 10, wherein the first and second transistor dies of each of the power stage inlays are configured as vertical devices with first and second load terminals disposed on opposite sides of the respective transistor die.

12. The power semiconductor module arrangement of claim 1, further comprising a plurality of passive elements mounted on the upper side of the circuit carrier, and wherein at least some of the passive elements are electrically connected to the terminals of each of the power stage inlays by the conductive connectors.

13. The power semiconductor module arrangement of claim 12, wherein the passive elements comprise a discrete inductor mounted over each one of the power stage inlays, wherein each of the discrete inductors is mounted such that a lower lead or contact of the respective discrete inductor is electrically connected to one of the terminals of the power stage inlays by one of the conductive connectors, and wherein each of the discrete inductors comprises a conductive core that is exposed from an upper side of the respective discrete inductor that is opposite from the upper side of the circuit carrier.

14. The power semiconductor module arrangement of claim 1, wherein each of the power stage inlays are laminate devices composing a plurality of laminate dielectric layers and structured metallization layers stacked on the laminate dielectric layers, and wherein the terminals are provided from outermost ones of the structured metallization layers.

15. A method of producing a power semiconductor module arrangement, the method comprising:
providing a plurality of power stage inlays that each comprise first and second transistor dies and a driver die configured to control switching of the first and second transistor dies; and
embedding each of the power stage inlays within an electrically insulating substrate;
forming an upper metallization layer on an upper side of the electrically insulating substrate,
wherein each of the power stage inlays are modular units comprising terminals that are electrically connected to the first and second transistor dies and the driver die, and
wherein the upper metallization layer comprises conductive connectors that extend over the power stage inlays and connect with the terminals of each of the power stage inlays.

16. The method of claim 15, wherein embedding the plurality of power stage inlays comprises forming a dielectric resin that contacts outer edge sides of the power stage inlays.

17. The method of claim 16, wherein embedding the plurality of power stage inlays further comprises providing a dielectric core structure and arranging the power stage inlays on or within the dielectric core structure.

18. The method of claim 17, wherein the dielectric core structure is provided to comprise one or more recesses extending from an upper surface of the dielectric core structure, and wherein embedding the plurality of power stage inlays further comprises:
arranging one or more of the power stage inlays within the one or more recesses; and
forming the dielectric resin around the power stage inlays within the one or more recesses.

19. The method of claim 18, wherein embedding the plurality of power stage inlays comprises:
arranging a plurality of the power stage inlays within one of the recesses; and
forming the dielectric resin around each of the power stage inlays within the one of the recesses.

20. The method of claim 17, wherein the dielectric core structure is provided to comprise one or more openings that extend completely from the upper surface of the dielectric core structure to a rear surface of the dielectric core structure, wherein the method further comprises:
providing a temporary carrier; and
arranging each one of the power stage inlays on the temporary carrier before forming the dielectric resin.

21. The method of claim 16, wherein embedding the plurality of power stage inlays further comprises:
providing a temporary carrier; and
arranging each one of the power stage inlays on the temporary carrier before forming the dielectric resin.

22. The method of claim 16, further comprising providing a printed circuit board, and wherein embedding the plurality of power stage inlays further comprises:
arranging each one of the power stage inlays on the printed circuit board; and
forming the dielectric resin over each one of the power stage inlays and on the printed circuit board.

23. The method of claim 15, wherein each of the power stage inlays comprise a plurality of upper I/O terminals disposed on an upper side of the respective power stage inlay, and wherein the conductive connectors are formed to comprise I/O connectors that extend over and are in direct ohmic contact with the upper I/O terminals.

24. The method of claim 15, wherein the power stage inlays are each configured as integrated half-bridge circuits, and wherein the first and second transistor dies of the power stage inlays form the high-side switch and the low-side switch of the integrated half-bridge circuit, respectively.

25. The method of claim 15, wherein the first and second transistor dies of each of the power stage inlays are configured as vertical devices with first and second load terminals disposed on opposite sides of the respective transistor die.

26. The method of claim 15, further comprising mounting a plurality of passive elements mounted on the upper side of the electrically insulating substrate, wherein at least some of the passive elements are electrically connected to the terminals of each of the power stage inlays by the conductive connectors.

27. The method of claim 26, wherein mounting the plurality of passive elements comprises mounting a discrete inductor mounted over each one of the power stage inlays, wherein each of the discrete inductors is mounted such that a lower lead or contact of the respective discrete inductor is electrically connected to one of the terminals of the power stage inlays by one of the conductive connectors, and wherein each of the discrete inductors comprises a conductive core that is exposed from an upper side of the respective discrete inductor that is opposite from the upper side of the circuit board.
